(19) United States
(12) Patent Application Publication
(10) Pub. No.: US 2004/0173898 A1
(43) Pub. Date: Sep. 9, 2004

(54) Semiconductor apparatus having system-in-package arrangement with improved heat dissipation

(76) Inventors: Makoto Ito, Yokohama-shi (JP); Takeshi Sekiguchi, Yokohama-shi (JP); Sousaku Sawada, Yokohama-shi (JP)

Correspondence Address: Smith, Gambrell & Russell, Suite 800, 1850 M Street, N.W., Washington, DC, 20036, US

(21) Appl. No.: 10/739,536

(22) Filed: Dec. 19, 2003

(30) Foreign Application Priority Data
Jan. 6, 2003 (JP) 2003-000562

(51) Int. Cl. H01L 23/34

(52) U.S. Cl. 257/718

(57) ABSTRACT

The present invention provides a semiconductor apparatus that has a system-in-package form and an effective configuration of heat dissipation. The apparatus of the present invention comprises a substrate providing a first surface, a second surface and a plurality of via-holes filled with metal and connecting the first and second surfaces. A semiconductor device and other electronic components are provided on the first surfaces. The semiconductor device is mounted on a metal sheet that is in contact with a portion of the plurality of via-holes. The semiconductor device, electronic components and the metal sheet are molded with resin. Heat generated by the semiconductor device can be dispersed to the metal sheet, transmitted to via-holes and effectively dissipated to an outside of the apparatus.

### BACKGROUND OF THE INVENTION

1. Field of the Invention

This invention relates to a semiconductor apparatus called as a system-in-package, in which a semiconductor device is mounted on a substrate with a plurality of via-holes to electrically connect both surfaces of the substrate and is resin-molded.

2. Description of Prior Art

A hybrid integrated circuit (HIC) is well known configuration for a high-frequency amplifier over 1 GHz. In the HIC, active circuit elements, such as a transistor, and passive elements, such as a capacitor and a resistor, are integrally mounted on a wiring substrate. The wiring substrate mounted circuit elements thereon is covered and sealed with a metal lid. The wiring substrate also provides a plurality of lead terminals on the side thereof for transmitting signals and for supplying bias thereto.

In such HIC, since the lead terminals transmit the signal, an impedance matching of these lead terminals may influence the quality of the transmitted signal, as the frequency becomes higher. Wiring patterns in the HIC and on the motherboard mounted the HIC thereon, may be maintained with impedance-matched state. However, the lead terminal can not match its predetermined transmission impedance because the lead terminal is exposed in air. Thus, the impedance miss-matched lead terminal may cause signal reflection and degrade the quality of the transmitted signal.

Recently, a new encasing technique for a semiconductor device is proposed and practically going to use, which is called as a system-in-package (hereinafter denoted as SIP). In the SIP, active elements with bare chip form and passive elements with die form are mounted on one side of a substrate, and these circuit elements are resin-molded with wiring provided on the surface of the substrate. Circuit elements on the substrate are electrically connected to the other side of the substrate by via-holes provided within the substrate and filled with metal.

The SIP is manufactured such that a relatively wide substrate, on which a plurality of wiring patterns, same to each other, is periodically formed and circuit elements are mounted thereon, is resin-molded and separated so as to isolate each wiring pattern. This manufacturing method, similar to the production of the integrated circuit, enables to mass-produce the semiconductor apparatus in one time.

Surface mounting of the SIP on the motherboard performs the electrical connection between the SIP and the motherboard. Namely, the surface mounting is performed such that providing soldering balls on the end of the via-holes, putting the SIP on the motherboard so as to be in contact the soldering balls with corresponding wiring patterns on the motherboard, and fusing the soldering balls.

However, in an amplifier with high power at a high frequency, power consumption of the active element such as a transistor, often amounts to several watts. In such high-powered and high frequency amplifier, the semiconductor device may thermally break without effective heat dissipation because the operational temperature of the semiconductor device exceeds 125 defined as the 25° C. maximum junction temperature. Even if the transistor may not thermally break, the performance of the transistor may degrade.

In the HIC, a metal block may be provided under the wiring substrate such that the entire substrate is in contact with the metal block to effectively dissipate heat generated by the semiconductor device mounted on the substrate. On the other hand in the SIP, the semiconductor device must be mounted on the substrate providing via-holes, the SIP may not adopt such effective arrangement as the HIC.

One solution that increases the number and the density of via-holes provided in the substrate is proposed for the SIP. However, the number of via-holes provided beneath the semiconductor device would be restricted when the plane size of the semiconductor device and the diameter of via-hole are compared. To increase the number of via-holes by reducing the diameter thereof would not be effective for heat dissipation because the thermal conduction depends on the total cross section of the via-holes.

### SUMMARY OF THE INVENTION

One object of the present invention is to provide a semiconductor apparatus having a SIP configuration in which heat generated by a semiconductor device may be effectively dissipated to the outside.

According to the present invention, a semiconductor apparatus comprises a substrate, a metal sheet, a semiconductor device and a molding resin. The substrate has a first and second surfaces. The first surface and the second surface are connected with a plurality of via-holes filled with metal. The first surface mounts the semiconductor device thereon through the metal sheet. The metal sheet preferably mounts the entire portion of the semiconductor device. The molding resin molds the semiconductor device and the metal sheet, and covers the first surface of the substrate.

In the semiconductor apparatus thus arranged, since heat generated by the semiconductor device is transmitted to the outside of the apparatus through the metal sheet and the plurality of via-holes, the thermal stability of the semiconductor device may be maintained.

The substrate may include a first region and a second region. The first region has a first type of via-holes provided with a first pitch and the second region has a second type of via-holes provided with a second pitch. The second pitch is greater than the first pitch, and the metal sheet is mounted on the first region. This configuration of the substrate and the metal sheet may enhance heat dissipation from the semiconductor device to the outside.

The metal sheet is preferably made of copper or copper-tungsten alloy and the semiconductor device is preferably made of GaAs. The copper has a good thermal conductivity, while the copper-tungsten alloy has a thermal expansion co-efficient comparative to that of the semiconductor device including GaAs.

The substrate preferably mounts a plurality of electronic components with a chip form on the first surface thereof, and these components are molded by the resin simultaneously with the semiconductor device and the metal sheet.

### BRIEF DESCRIPTION OF DRAWINGS

FIG. 1 is a perspective view of a semiconductor apparatus of the present invention;

FIG. 2 is a cross sectional view when the semiconductor apparatus is going to be mounted on a motherboard;

FIG. 3 is a plan view showing an embodiment of the substrate used in the present invention;

FIG. 4 illustrates results of heat dissipation of the semiconductor apparatus of the present invention; and

FIG. 5 illustrates results of heat dissipation of conventional configurations.

### DETAILED DESCRIPTION OF PREFERRED EMBODIMENTS

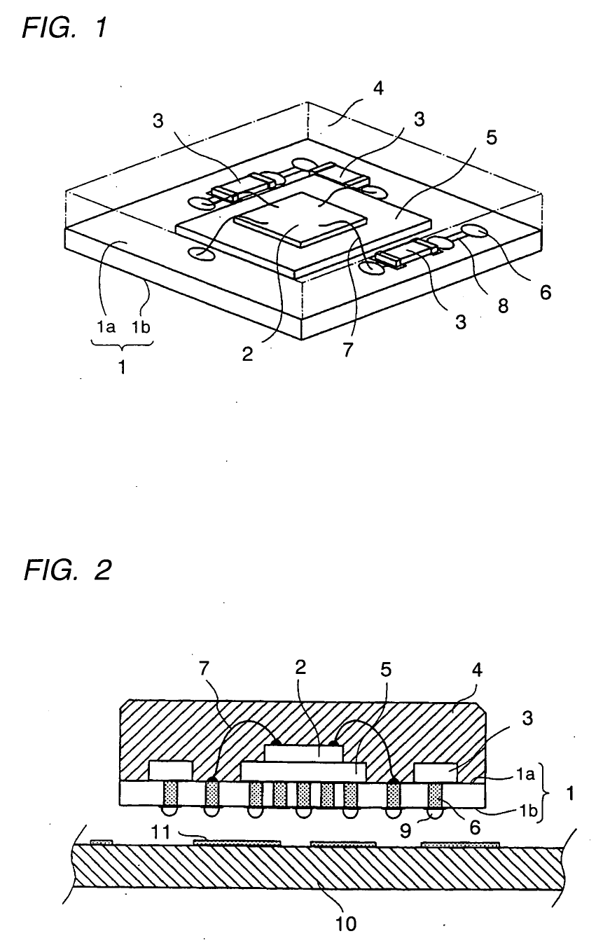

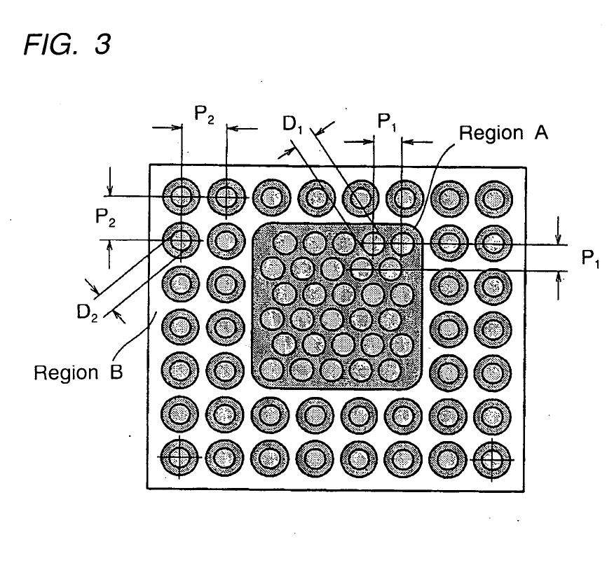

Preferred embodiment of the present invention will be described as referring to accompanying drawings. FIG. 1 shows a semiconductor apparatus formed by a system-in-package (SIP) technique, FIG. 2 is a cross sectional view showing an arrangement of the semiconductor apparatus mounted on a motherboard, and FIG. 3 shows a substrate of the SIP viewed from the bottom side.

FIG. 1 shows a final configuration of an apparatus formed by the SIP technique. On a substrate 1 having a first surface 1a and a second surface 1b, a semiconductor device 2 such as a transistor is mounted. Other circuit components 3, such as chip resistors and chip capacitors, are also mounted on the first surface 1a. The semiconductor device 2 is assembled on the first surface la by the surface mounting technology, in which electronic pads on the semiconductor device are electrically connected to via-holes 6 and wiring patterns 8 provided on the first surface la of the substrate 1 by bonding wires 7. Chip resistors and chip capacitors are also mounted by the solder paste and are electrically connected to the via-hole 6. In FIG. 2, although the bonding wire 7 connects the semiconductor device 2 directly to the via-hole 6, the bonding wire 7 may connect the semiconductor device 2 to the wiring pattern 8 extending from the via-hole 6.

In the present invention, the semiconductor device 2 is mounted on the substrate 1 through the metal sheet 5. A molding resin 4 molds and secures the semiconductor device 2 and electronic components 3. The apparatus shown in FIG. 1 may be formed such that a plurality of semiconductor devices 2 and electronic components 3 are installed on a large substrate, molded in a lump by a resin and divided into an individual apparatus. In this case, the substrate 1 and the resin 4 have a same planar dimension, an outer shape of which becomes a flat rectangle.

On the first surface 1a of the substrate 1, a wiring pattern 8 is provided such that an amplifier, which is constituted by the combination of the semiconductor device 2 and the electronic components 3, is formed. As shown in FIG. 2, solder bumps 9 are provided in the second surface 1b of the substrate 1 to electrically connect the apparatus to wiring patterns 11 provided on the motherboard 10. Wiring pattern 8 on the first surface 1a is electrically connected to another wiring pattern on the motherboard 10 by a plurality of via-holes formed at a predetermined position. A metal, such as gold, fills within the via-hole 6.

The device thus configured is installed on the motherboard 10 by the surface mounting technique to obtain an expected function. Via-hole 6 performs an electrical connection between the motherboard 10 and the device. Solder bumps formed and exposed on the top of the via-holes 6 secure the electrical connection therebetween by the re-flow soldering. It may be applicable that solder bumps 9 are formed on the wiring pattern 11 on the motherboard 10 and the via-holes 6 are connected to these bumps by the re-flow soldering.

As shown in FIG. 3, several types of via-holes 6 may be formed in the substrate 1 depending on the application thereof For example, a region A, where the semiconductor device 2 is to be mounted, provides a first type of the via-hole 6a with a diameter D₁, for example 0.125 mm, and relatively condensed pitch P₁, for example 0.15 mm. While the rest region, region B, provides a second type of the via-hole 6b with a diameter D₂, for example 0.15 mm, and a sparse pitch P₂ of 0.25 mm.

On a region of the first surface la corresponding to the region A of the second surface 1b, the semiconductor device 2 is mounted via the metal sheet 5. By connecting the metal sheet 5 to the metal filing within the via-hole 6, heat generated by the semiconductor device 2 is effectively dissipated to the outside of the substrate 1. Further, the region A has a configuration that the via-hole provided therein is disposed with the condensed pitch, by which the metal sheet can be in contact with a number of the via-hole and the efficiency to dissipate heat can be enhanced.

The metal sheet 5 may be connected to the via-hole 6 by solder or eutectic metal such as tin-gold. (AuSn) The metal filling the via-hole is generally gold. Another metal with good thermal conductivity and good electrical conductivity may be applicable. In the drawing, the region B provides the via-hole in entire. It may applicable that the via-hole 6 in the region B provides the specific position corresponding to the wiring pattern 8 formed on the first surface 1a.

The substrate is made of resin such as FR4. However, the material for the substrate is not restricted to such resin. Materials generally used in a wiring substrate are also applicable. A thickness of the substrate 1 is about 0.5 mm. A multi-layered substrate is also applicable in the present invention. The mold resin 4 is typically made of epoxy resin with a thickness of about 0.7 mm. The outer surface of the resin 4 is formed in planar.

In the present invention, the semiconductor device 2 is mounted on the substrate 1 through the metal sheet 5, and the heat generated by the semiconductor device 2 can be dissipated through the metal sheet 5. The plane size of the metal sheet 5 is preferable greater than that of the semiconductor device 2 and the entire portion of the device 2 is preferably mounted within the metal sheet 5. These arrangement enables to effectively dissipate the heat to the outside the substrate 1. The thickness of the metal sheet 5 is preferably about 0.3 mm from the handling at the production viewpoint. A thinner sheet results in not only the inefficient handling but also the inferior thermal conductivity, which impedes the heat to effectively dissipate to the entire metal sheet 5.

The metal sheet is preferably made of copper or sintered metal of copper and tungsten. The copper is a material with a high thermal conductivity and can be obtained in relatively low price. Although the thermal conductivity of the copper-tungsten is not comparable to that of the copper, the expansion co-efficient of the copper-tungsten is nearly comparable to that of the semiconductor device. In particular, when the device is made of gallium arsenide or silicon, the thermal expansion co-efficient is nearly same as that of the copper-tungsten. In the case that the metal sheet is made of copper-tungsten, a mechanical stress due to the difference of the thermal expansion co-efficient between the metal sheet 5 and the semiconductor device 2 can be reduced, which enhance the long-term reliability of the device.

The thermal expansion co-efficient of gallium arsenide is 6.8(×10⁻⁶/K), while that of the copper-tungsten is from 5.0 to 8.5(×10⁻⁶/K). On the other hand, that of copper is around 16(×10⁻⁶/K), which is one figure greater than that of the gallium arsenide. The thermal expansion co-efficient of the resin is widely distributed from 30 to 200(×10⁻⁶/K) that is one figure greater than that of gallium arsenide, too. Thus, the metal sheet 5 made of copper is effectively used when the thermal conductivity is important. While, the metal sheet 5 made of copper-tungsten is utilized when the thermal expansion co-efficient is major subject.

The thickness of the semiconductor device 2 is thin, preferably from 30 to 70 μm. Active devices, such as transistors, are formed on the top surface of the semiconductor device 2, while the back surface thereof provides a metal, for example coated with gold, with a thickness of about 10 μm to mount the device 2 on the metal sheet 5. The mounting of the device 2 is performed by eutectic metal, such as tin-gold. Another configuration of the semiconductor device, for example, via-holes filled with a metal from the top surface to the back metal are provided, is also applicable to improve not only from the high-frequency performance but also from the viewpoint of the thermal stability.

Thus, an embodiment of the present invention is described. In the drawings, the configuration that the substrate 1 mounts the unique semiconductor device is described. The invention is not restricted to such configuration. A plurality of semiconductor devices is mounted on the substrate 1 may be also applicable to the present invention. In the drawing, the metal sheet 5 with the semiconductor device 2 is provided in the center of the substrate 1. However, the position of the semiconductor device can be optional according to the circuit to be realized by the SIP apparatus. Further, in the case that a plurality of semiconductor devices is provided, the metal sheet 5 with a wider area can be commonly used in respective devices 2 or distinct metal sheets may be provided for individual semiconductor devices.

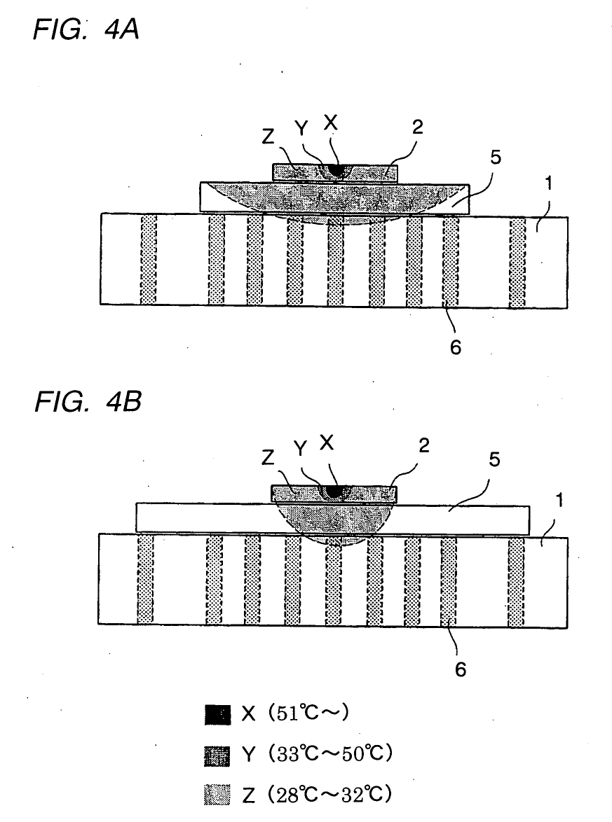

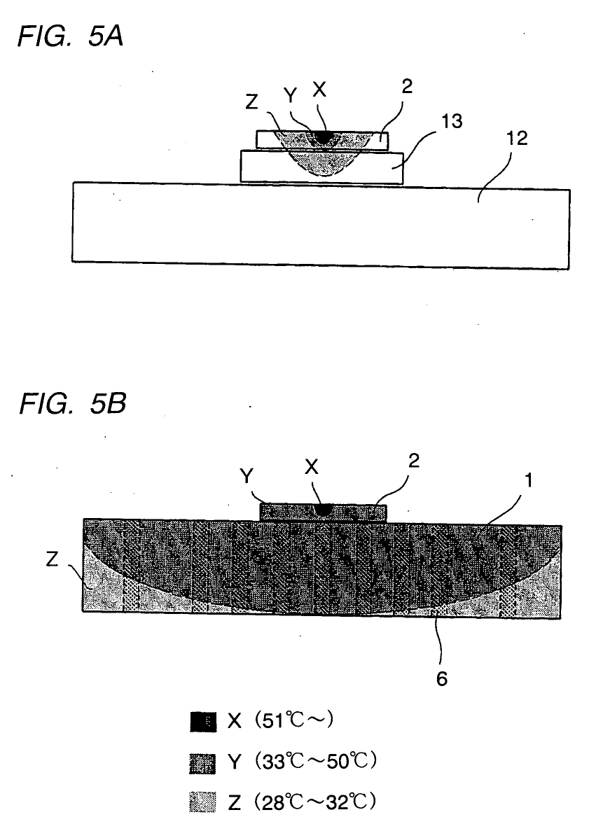

FIG. 4 and FIG. 5 show results of thermal dissipation effect of the present invention. FIG. 4A shows a temperature distribution when the area of the metal sheet 5 is twice larger than that of the semiconductor device 2, and FIG. 4B is a results when the area of the metal sheet 5 is three times larger than that of the semiconductor device 2. FIG. 5A is a result when the semiconductor device 2 is mounted on the copper-tungsten sheet 12 through the chip carrier 13 and FIG. 5B is another result when the semiconductor device 2 is directly mounted on the substrate 1. In the drawings, the area of 6 μm² and an amount of 6 W is assumed for the heat generation of the semiconductor device 2.

In FIG. 4, the device 2 is a transistor made of GaAs, which is quite popular in a high frequency application. The transistor has a thickness of 30 μm and a size of 0.75 mm×0.725 mm. The back surface of the device 2 is wholly plated with gold. The substrate 1 is made of FR4 with a thickness of 0.5 mm and a size of 3.5 mm square. Via-holes are filled with gold. The metal sheet 5 is made of copper and has a thickness of 0.5 mm. The size of the metal sheet 5 is 1.0 mm in length and 2.0 mm in width in the case of FIG. 4A, which is twice larger than that of the device 2. While in FIG. 4B, the size is 1.0 mm in length and 3.0 mm in width, which is three times larger than that of the device 2. The connection between the device 2 and the metal sheet 5, and the connection between the metal sheet 5 and the via-holes 6 are preformed by an eutectic metal, such as AuSn.

In FIG. 4A, a temperature increase is found in nearly whole area of the metal sheet 5. Namely a region X where the temperature is over 51° C. is found around the heat generating portion, a region Y where the temperature is over 33° C. and below 50° C. appears around the region X, and another region Z where the temperature is over 28° C., and below 32° C., appears in rest portion of the metal sheet 5. The highest temperature in the region X reaches 61.3° C.

In FIG. 4B, the region X where the temperature is over 51° C., the region Y where the temperature is over 33° C. and below 50° C., and the region Z where the temperature is over 28° C. and below 32° C., are only recognized around the device 2. The highest temperature reaches 60.6° C., which is comparative to the case shown in FIG. 4A. Most portion of the metal sheet shows a room temperature.

FIG. 5 shows conventional cases, where the transistor 2 is made of GaAs and has a thickness of 30 μm and a size of 0.75 mm×0.725 mm coated in the whole back surface with gold. These conditions are same as the case shown in FIG. 4. In FIG. 5A, the device 2 is mounted on the metal sheet 12 via a chip carrier 13. This chip carrier is made of CuW and has 0.3 mm in thickness and 1.0 mm×1.0 mm in size. In FIG. 5B, the device 2 is directly mounted on the substrate 1 without a metal sheet 5. The substrate 1 has the same as that used in the case of FIG. 4. The connection between the device 2 and the metal sheet 5, and that between the metal sheet 5 and the via-holes 6 are performed by the eutectic metal of AuSn.

FIG. 5A simulates a configuration that the device 2 is mounted on the metal sheet 12 with relatively large area through the chip carrier 13 made of CuW and generates heat under the 1 W power consumption. The region X, Y and Z are recognized in only around the device 2. Where, the temperatures of respective regions X, Y and Z are same as the case in FIG. 4. The highest temperature reaches 56.8° C., while the temperature of the rest region except around the device 2 is controlled below 30° C. due to the heat-dissipating arrangement using the chip carrier 13.

FIG. 5B shows a temperature distribution when the device 2 generates heat under the power consumption of 1 W. The highest temperature at the region X around the device 2 reaches 67° C. Moreover, the region Y where the temperature is over 33° C. and below 50° C. covers the whole substrate 1, and the temperature at the edge of the substrate 1 reaches about 40° C.

From the investigation described above, it is evident, for the SIP device using a semiconductor device with a large heat generation, to suppress the increase of the temperature of the substrate 1. The metal sheet, such as shown in FIG. 4A and FIG. 4B and disposed between the device 2 and the substrate 1, improves the heat-dissipating characteristic so as to close the temperature distribution thereof to the case where the device 2 is mounted on the metal sheet with a great area via the chip carrier.

The SIP device of the present invention may be mounted on the motherboard by the surface mounting method. The heat-dissipating efficiency may increase, as the size of the metal sheet becomes larger.

What is claimed is:

1. A semiconductor apparatus, comprising:
a substrate having a first surface, a second surface and a plurality of via-holes for electrically connecting the first surface and the second surface;
a metal sheet provided on the first surface of the substrate;
a semiconductor device mounted on the metal sheet; and
a resin for molding the semiconductor device and the metal sheet.

2. The semiconductor apparatus according to claim 1, wherein a size of the metal sheet is greater than a plane size of the semiconductor device, the metal sheet entirely mounting the semiconductor device thereon.

3. The semiconductor apparatus according to claim 1, wherein the metal sheet is in contact with a portion of the plurality of via-holes.

4. The semiconductor apparatus according to claim 1, wherein the substrate includes a first and second regions, the first region having a first type of via-holes provided with a first pitch and the second region having a second type via-holes provided with a second pitch greater than the first pitch, and
wherein the metal sheet is mounted on the first region of the substrate.

5. The semiconductor apparatus according to claim 4, wherein the metal sheet is in contact with the first type of via-holes.

6. The semiconductor apparatus according to claim 1, wherein the metal sheet is made of copper.

7. The semiconductor apparatus according to claim 1, wherein the metal sheet is made of copper-tungsten alloy.

8. The semiconductor apparatus according to claim 1, wherein the semiconductor device is a field effect transistor made of GaAs.

9. The semiconductor apparatus according to claim 1, wherein the substrate further mounts a plurality of electronic components on the first surface thereof.

10. The semiconductor apparatus according to claim 9, wherein the plurality of electronic components has a chip form.
